(19) United States
(12) Patent Application Publication
(10) Pub. No.: US 2007/0209677 A1
(43) Pub. Date: Sep. 13, 2007

(54) Self-Cleaning Catalytic Chemical Vapor Deposition Apparatus And Cleaning Method Thereof

(76) Inventors: Makiko Kitazoe, Chiba (JP); Shuji Osono, Chiba (JP); Hiromi Itoh, Chiba (JP); Kazuya Saito, Chiba (JP); Shin Asari, Chiba (JP)

Correspondence Address: ARENT FOX PLLC, 1050 CONNECTICUT AVENUE, N.W., SUITE 400, WASHINGTON, DC, 20036, US

(21) Appl. No.: 10/591,905

(22) PCT Filed: Mar. 10, 2005
(86) PCT No.: PCT/JP05/04205

§ 371 Date: Nov. 6, 2006

(30) Foreign Application Priority Data
Mar. 10, 2004 (JP) 2004-067174

(51) Int. Cl. C23C 16/00; B08B 5/00; B08B 3/12

(52) U.S. Cl. 134/1; 118/715; 118/723 R

(57) ABSTRACT

Provided is a self-cleaning catalytic chemical vapor deposition apparatus which suppresses the corrosion-induced degradation of a catalytic body by a cleaning gas without heating a catalytic body to not less than 2000° C. and permits practical cleaning rates and good cleaning at low cost. With conductors 5a, 5b which supply a constant current to a catalytic body 4 within a reaction chamber 2 from a heating power supply 6 and terminals 6a, 6b of the heating power supply 6 kept electrically insulated from the reaction chamber 2, a cleaning gas containing halogen elements is introduced into the reaction chamber 2 which has been evacuated, and the catalytic body 4 is heated by the energization from the heating power supply 6. An active species generated by this heating is caused to react with an adhering film which adheres to the interior of the reaction chamber 2, whereby the adhering film is removed. During this removal of the adhering film, a DC bias voltage having an appropriate polarity and an appropriate value is applied from a constant-voltage power supply 8 to the conductor 5b of the heating power supply 6.

### TECHNICAL FIELD

The present invention relates to a self-cleaning catalytic chemical deposition apparatus in the interior of which corrosion-induced degradation of a catalytic body by a cleaning gas is suppressed and which permits practical cleaning rates and good cleaning, and a cleaning method of the self-cleaning catalytic chemical deposition apparatus.

### BACKGROUND ART

In the manufacture of various kinds of semiconductor devices, LCD's (liquid crystal displays) and the like, for example, the CVD method (chemical vapor deposition method) has hitherto been known as a method of forming a thin film on a substrate.

The thermal CVD method, the plasma CVD method and the like have hitherto been known as the CVD method. In recent years, however, the catalytic chemical vapor deposition method (also called the Cat-CVD method or the hot wire CVD method) has begun to be put to practical use; in this method, a heated wire of tungsten and the like (hereinafter called “catalytic body”) is used as a catalyst, and a thin film is deposited on a substrate by decomposing a raw material gas supplied to a reaction chamber with the aid of the catalytic action by this catalytic body.

The catalytic CVD method can perform film formation at low temperatures compared to the thermal CVD method and is free from the problem that damage remains in a substrate by the generation of a plasma as in the plasma CVD method, or the like. Therefore, the catalytic CVD method is attracting attention as a film formation method of next-generation semiconductor devices and display devices, such as LCD, and the like.

In a catalytic CVD apparatus which performs film formation by this catalytic CVD method, as with a thermal CVD apparatus and a plasma CVD apparatus, when a raw material gas decomposed in the film formation process forms a deposited film on a substrate, part of the decomposed raw material gas adheres as a film also to inner walls of a reaction chamber, a substrate stage and the like.

When these adhering films become deposited, they exfoliate before long, float up within the reaction chamber, and adhere to the substrate, thereby resulting in a decrease in treatment quality.

For this reason, films which have adhered to inner walls of a reaction chamber, a substrate stage and the like (hereinafter called “adhering films”) need to be removed. As an in situ cleaning method to remove the adhering films, there has hitherto been generally adopted a method which involves introducing a cleaning gas containing halogen elements such as HF, NF₃, SF₆ and CF₄, into a reaction chamber and causing a halogen-containing radical species which is generated by the decomposition of a cleaning gas by a catalytic body, which is a heating element which has been heated, to react with the adhering films, whereby the adhering films are removed.

Because in such a conventional cleaning method, a heated catalytic body such as tungsten used in the decomposition of a raw material gas is used also to decompose the above-described cleaning gas, part of a halogen-containing radical species generated at this time reacts with the catalytic body and the catalytic body is etched, causing corrosion-induced degradation, whereby prescribed heat generation characteristics cannot be obtained when film formation is to be performed after cleaning, posing the problem that the reproducibility of the film deposition rate is lost, or the like.

For this reason, in order to solve problems as described above, there have been proposed cleaning methods which involve heating a catalytic body of tungsten and the like to not less than 2000° C., thereby to suppress the etching (corrosion-induced degradation) of the catalytic body resulting from a reaction between the catalytic body and a cleaning gas (refer to Patent Document 1, for example).

Patent Document 1: Japanese Patent Laid-Open No. 2001-49436

### DISCLOSURE OF THE INVENTION

However, in the cleaning method described in Patent Document 1 above, it is necessary to heat a catalytic body (a heating wire) of tungsten and the like to not less than 2000° C. Therefore, there is a possibility that the catalytic body may degrade due to the evaporation of the catalytic body itself which has been heated to not less than 2000° C. and that the interior of a reaction chamber (a treatment chamber) may be polluted by the component elements of the catalytic body resulting from this evaporation, and there is room for improvement.

By the heating of the catalytic body to not less than 2000° C., also component members provided near the catalytic body and inner walls of the reaction chamber are heated to high temperatures by the radiation heat from the catalytic body. Therefore, it is necessary to use members which have heat resistance and small gas emissions ascribable to heat, the members capable of being used are limited, cost rises and the like. Thus there is room for improvement.

In view-of such problems, the present invention has as its object the provision of a self-cleaning catalytic chemical vapor deposition apparatus which suppresses the corrosion-induced degradation by a cleaning gas without heating a catalytic body to not less than 2000° C. and permits practical cleaning rates and good cleaning at low cost, and a cleaning method of the apparatus.

To achieve the above object, the first aspect of the present invention for a self-cleaning catalytic chemical vapor deposition apparatus of the present invention has the constitution that in a catalytic chemical vapor deposition apparatus which forms a thin film by using the catalytic action of a catalytic body which is resistance heated within a reaction chamber capable of being evacuated to a vacuum, the apparatus comprises a power supply to apply a bias voltage to the catalytic body and a changeover switch which changes the polarity of the bias voltage to be applied, and which removes an adhering film which has adhered to the interior of the reaction chamber without etching the catalytic body itself on the basis of a radical species generated when an introduced cleaning gas comes into contact with the resistance heated catalytic body and is decomposed, the bias voltage applied to the catalytic body, and a polarity of the bias voltage.

The second aspect of the present invention is characterized in that in addition to the aforementioned constitution, a radical species generator which decomposes the cleaning gas into a radical species and introduces the radical species into the reaction chamber is provided.

The third aspect of the present invention is characterized in that the cleaning gas is a mixed gas of a halogen—containing gas and either an inert gas or a reducing gas.

The fourth aspect of the present invention is characterized in that the cleaning gas contains either an inert gas or a reducing gas and that a polarity of the bias voltage based on the kind of the inert gas and the reducing gas is obtained.

The fifth aspect of the present invention has the constitution that the cleaning gas is a mixed gas of a halogen-containing gas and a reducing gas when the bias voltage of the prescribed polarity is zero.

The sixth aspect of the present invention has the constitution that the halogen-containing gas is any of gases selected from the group consisting of NF₃, HF, C₂F₆, C₃F₈, SF₆, CF₄, CClF₃, C₂ClF₅ and CCl₄ or combinations of the gases, that the reducing gas is H₂, and that the inert gas is a noble gas.

The seventh aspect of the present invention has the constitution that the cleaning gas is a mixed gas of a halogen-containing gas and H₂ and that the bias voltage of a positive polarity is applied.

The eighth aspect of the present invention has the constitution that the cleaning gas is a mixed gas of a halogen-containing gas and Ar and that the bias voltage of a negative polarity is applied.

In the ninth aspect of the present invention, there is provided a monitoring device which detects the occurrence of etching of the catalytic body itself on the basis of electric resistance of the catalytic body.

The tenth aspect of the present invention for a cleaning method of a catalytic chemical vapor deposition apparatus of the present invention has the constitution that in a cleaning method of a catalytic chemical vapor deposition apparatus which forms a thin film by using the catalytic action of a catalytic body which is resistance heated within a reaction chamber capable of being evacuated to a vacuum, the cleaning method comprises a step of applying a bias voltage of a prescribed polarity to a catalytic body which is resistance heated, a step of introducing a cleaning gas, a step in which the cleaning gas comes into contact with the catalytic body which has been resistance heated and is decomposed to generate a radical species, and a step of removing an adhering film which has adhered to the interior of a reaction chamber without etching the catalytic body itself.

The eleventh aspect of the present invention is characterized in that the step of introducing a cleaning gas is a step of decomposing the cleaning gas into a radical species and introducing the radical species into the reaction chamber.

The twelfth aspect of the present invention is characterized in that the cleaning gas is a mixed gas of a halogen-containing gas and either an inert gas or a reducing gas.

The thirteenth aspect of the present invention is characterized in that the cleaning gas contains either an inert gas or a reducing gas and that a bias voltage of a polarity determined on the basis of the kind of the inert gas and the reducing gas is applied.

The fourteenth aspect of the present invention is characterized in that the cleaning gas is a mixed gas of a halogen-containing gas and a reducing gas when the bias voltage of the prescribed polarity is zero.

The fifteenth aspect of the present invention is characterized in that the halogen-containing gas is any of gases selected from the group consisting of NF₃, HF, C₂F₆, C₃F₈, SF₆, CF₄, CClF₃, C₂ClF₅ and CCl₄ or combinations of the gases, that the reducing gas is H₂, and that the inert gas is a noble gas.

The sixteenth aspect of the present invention is characterized in that the cleaning gas is a mixed gas of a halogen-containing gas and H₂ and that the bias voltage of a positive polarity is applied.

The seventeenth aspect of the present invention is characterized in that the cleaning gas is a mixed gas of a halogen-containing gas and Ar and that the bias voltage of a negative polarity is applied.

The eighteenth aspect of the present invention is characterized in that the occurrence of etching of the catalytic body itself is monitored in situ on the basis of electric resistance during cleaning.

According to a self-cleaning catalytic chemical vapor deposition apparatus and a cleaning method of the apparatus of the present invention, the invention has the advantages that it is possible to suppress the corrosion-induced degradation of a catalytic body by a cleaning gas without heating the catalytic body to not less than 2000° C., and that it is possible to remove an adhering film which has adhered to inner walls and the like of a reaction chamber at practical cleaning rates.

Also, it is possible to deposit (form) a stable and good film on a substrate even during film formation because the corrosion-induced degradation of a catalytic body by a cleaning gas is suppressed.

Furthermore, because it is unnecessary to heat a catalytic body to not less than 2000° C. during cleaning, neither the degradation due to the evaporation of the catalytic body itself or the pollution of the interior of a reaction chamber with the component elements of the catalytic body occurs. In addition, it becomes possible to reduce cost because inexpensive members having a low melting point can be used.

### BRIEF DESCRIPTION OF THE DRAWINGS

FIG. 1 is a schematic block diagram showing a self-cleaning catalytic chemical vapor deposition apparatus which performs cleaning by a cleaning method related to Embodiment 1 of the present invention;

FIG. 2 is a diagram which shows changes in the voltage generated between terminals of a heating power supply in a case where a bias voltage is applied and in a case where a bias voltage is not applied when “a mixed gas of NF₃ and H₂” is used as a cleaning gas;

FIG. 3 is a diagram which shows changes in the voltage generated between terminals of a heating power supply in a case where a bias voltage is applied and in a case where a bias voltage is not applied when “a mixed gas of NF₃ and Ar” is used as a cleaning gas;

FIG. 4 is a diagram which shows changes in the voltage generated between terminals of a heating power supply when “a mixed gas of NF₃ and H₂” or “a mixed gas of NF₃ and Ar” is used as a cleaning gas; and

FIG. 5 is a schematic block diagram showing a self-cleaning catalytic chemical vapor deposition apparatus which performs cleaning by a cleaning method related to Embodiment 3 of the present invention.

### DESCRIPTION OF SYMBOLS

1, 20 Self-cleaning catalytic chemical vapor deposition apparatus
2 Reaction chamber
4 Catalytic body
6 Heating power supply
8 Constant-voltage power supply
10 Controller
11 Vessel for cleaning gas decomposition
14 Monitor

### BEST MODE FOR CARRYING OUT THE INVENTION

The self-cleaning catalytic chemical vapor deposition apparatus of the present invention is a catalytic chemical vapor deposition apparatus which forms a thin film by using the catalytic action of a catalytic body which is resistance heated within a reaction chamber capable of being evacuated to a vacuum, which comprises a power supply to apply a bias voltage to the catalytic body and a changeover switch which changes the polarity of the bias voltage to be applied, and which removes an adhering film which has adhered to the interior of the reaction chamber without etching the catalytic body itself on the basis of a radical species generated when an introduced cleaning gas comes into contact with the resistance heated catalytic body and is decomposed, the bias voltage applied to the catalytic body, and a polarity of the bias voltage.

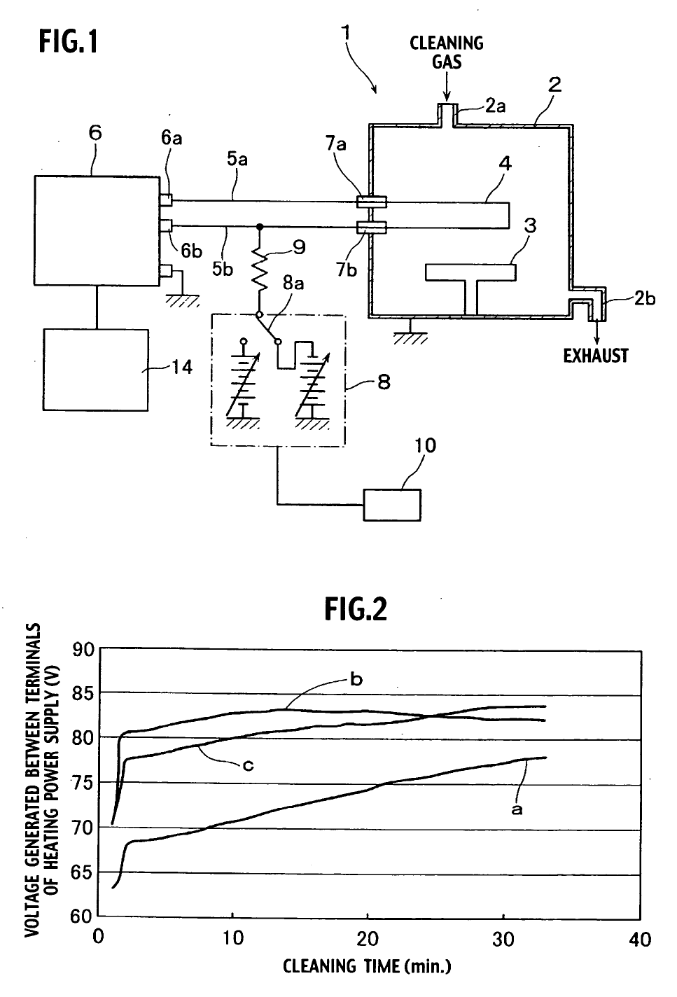

On the basis of FIGS. 1 to 5, best modes of the present invention will be described below by using like reference numerals for substantially like or corresponding members.

### Embodiment 1

First, Embodiment 1 will be described.

FIG. 1 is a schematic block diagram showing a self-cleaning catalytic chemical vapor deposition apparatus related to Embodiment 1 of the present invention.

This self-cleaning catalytic chemical vapor deposition apparatus 1 is provided with a reaction chamber 2, a substrate stage 3 which is provided within this reaction chamber 2 and on which a substrate (not shown) is to be placed, and a catalytic body 4 which is formed from a tungsten wire having a diameter of 0.5 mm, which has the catalytic action to decompose a raw material gas supplied into the reaction chamber 2 by heating the raw material gas.

The catalytic body 4 decomposes a cleaning gas supplied into the reaction chamber 2 by heating the cleaning gas during cleaning and generates a radical species by the contact of the clean gas with the catalytic body 4.

As the catalytic body having such a catalytic action, it is possible to use indium, molybdenum, tantalum, niobium and the like in addition to the tungsten wire and these alloys may also be used.

The reaction chamber 2 is provided with a gas supply system (not shown) which supplies a cleaning gas during cleaning of the reaction chamber 2 and supplies a raw material gas during film formation, and a gas evacuation system (not shown) which evacuates the reaction chamber 2 to a vacuum and adjusts the inner pressure of the reaction chamber 2. And as shown in FIG. 1, a cleaning gas is introduced from a gas supply port 2a and the reaction chamber 2 is evacuated to a vacuum from a gas exhaust port 2b.

A mixed gas of halogen-containing gases, such as NF₃, HF, C₂F₆, C₃F₈, SF₆, CF₄, CClF₃, C₂ClF₅ and CCl₄, and either reducing gases such as H₂ and the inert gases such as Ar is used as the cleaning gas.

As the inert gases, noble gases of the same kind as Ar can be used.

A heating power supply 6 which is a constant-DC power supply is connected to the catalytic body 4 via conductors 5a, 5b, and the catalytic body 4 is resistance heated when a DC voltage which is constant current controlled is applied from the heating power supply 6.

Each of the conductors 5a, 5b which are respectively connected to terminals 6a, 6b of the heating power supply 6 on one terminal side is electrically insulated by insulating materials 7a, 7b from the reaction chamber 2, and the reaction chamber 2 and the heating power supply 6 are grounded.

As described above, the heating power supply 6 and each of the conductors 5a, 5b are electrically insulated from the reaction chamber 2, and a power feed circuit to the catalytic body 4 is constituted by heating power supply 6 and each of the conductors 5a, 5b. This heating power supply 6 may be an AC power supply which is constant current controlled.

A constant-voltage power supply 8, which is a constant-DC power supply for controlling an electric potential applied from the heating power supply 6 to the catalytic body 4, is connected, via a resistor 9, to one conductor 5b which electrically connects the heating power supply 6 and the catalytic body 4 together.

The constant-voltage power supply 8 has a changeover switch 8a for changing the polarity of a bias voltage to be applied, and the polarity of a bias voltage to be applied can be changed by a control signal from a controller 10 which is connected.

Furthermore, by applying a bias voltage, which is controlled by a control signal from the controller 10 to a desired polarity and an electric potential value of positive polarity or negative polarity, to the catalytic body 4 via the resistor 9, the constant-voltage power supply 8 can control an electric potential to be applied from the heating power supply 6 to the catalytic body 4, i.e., a voltage across the terminals of the heating power supply 6 (details will be given later).

The polarity of a bias voltage to be applied is set in order to prevent the occurrence of etching of the catalytic body 4 itself which is resistance heated, and can be appropriately changed depending on the kind of an inert gas and a reducing gas which are introduced.

In Embodiment 1, there is provided a monitor 14 which detects the occurrence of etching of the catalytic body 4 itself by detecting a voltage across the output terminals 6a, 6b of the constant-current power supply 6.

In a case where a constant-current power supply is used to feed power for the resistance heating of the catalytic body 4, if the etching of the catalytic body 4 itself occurs during self-cleaning, the diameter of the catalytic body, which is usually formed from a fine wire, decreases and the electric resistance increases, with the result that the voltage across the output terminals of the set-current power supply increases.

Therefore, by detecting the voltage across the terminals during self-cleaning by use of the monitor 14, it is possible to detect the occurrence of etching of the catalytic body 4 itself.

Next, a description will be given of film formation and in-situ cleaning methods by use of the self-cleaning catalytic chemical vapor deposition apparatus 1 related to Embodiment 1.

With reference to FIG. 1, in the film formation treatment by the self-cleaning catalytic chemical vapor deposition apparatus 1 related to this embodiment, a substrate (not shown) is carried into the reaction chamber 2 and placed on the substrate stage 3.

Next, the interior of the reaction chamber 2 is purged with Ar gas or hydrogen gas while it is being evacuating to a vacuum. After that, a DC voltage is applied to the catalytic body 4, and the catalytic body 4 is heated by resistance heating to a prescribed temperature, for example, 1700° C. or so, while the pressure is being controlled to a prescribed pressure in the atmosphere of these purge gases.

Subsequently, a changeover is made to the introduction of a raw material gas, for example, a mixed gas of SiH₄ and H₂ into the reaction chamber 2 from the gas supply system through the gas supply port 2a, and the interior of the reaction chamber 2 is evacuated by the gas exhaust system through the gas exhaust port 2b, whereby an adjustment is made to a prescribed pressure.

At this time, the introduced raw material gas comes into contact with the catalytic body 4 heated to 1700° C. and is decomposed with the generation of a radical species, and a thin film is deposited on the substrate.

By repeating this treatment for the film formation process, part of the decomposed reaction gases adheres also to the inner walls of the reaction chamber 2, the substrate stage 3 and the like as deposited films.

For this reason, it is necessary for the catalytic chemical vapor deposition apparatus to clean the interior of the reaction chamber 2 at intervals of prescribed operating hours.

Next, a description will be given of a cleaning method of a catalytic chemical vapor deposition apparatus for removing adhering films which have adhered to the inner walls of the reaction chamber 2, the substrate stage 3 and the like by use of the self-cleaning catalytic chemical vapor deposition apparatus related to Embodiment 1.

The cleaning method of a catalytic chemical vapor deposition apparatus of the present invention is a cleaning method of a catalytic chemical vapor deposition apparatus which forms a thin film by using the catalytic action of the catalytic body 4 which is resistance heated within the reaction chamber 2 capable of being evacuated to a vacuum, and this cleaning method comprises a step of applying a bias voltage of a prescribed polarity to a catalytic body 4 which is resistance heated, a step of introducing a cleaning gas, a step in which the cleaning gas comes into contact with the catalytic body which has been resistance heated and is decomposed to generate a radical species, and a step of removing an adhering film which has adhered to the interior of a reaction chamber without etching the catalytic body itself.

The cleaning method will be described in detail below.

First, the interior of the reaction chamber 2 is purged with Ar gas or hydrogen gas while it is being evacuating to a vacuum. After that, the catalytic body 4 is heated by resistance heating to 1700° C., for example, while the pressure is being controlled to 65 Pa in the atmosphere of these purge gases.

At this time, a bias voltage is applied beforehand, with the polarity set at a negative polarity for the introduction of Ar gas and at a positive polarity for the introduction of hydrogen gas.

Next, by the changeover operation of introduction gases of the gas supply system, a cleaning gas is introduced into the reaction chamber 2 through the gas supply port 2a.

In this embodiment, a mixed gas of NF₃ (nitrogen trifluoride), which is a halogen-containing gas, and H₂ (hydrogen), which is a reducing gas, is introduced as the cleaning gas, each in an amount of 20 sccm.

Because hydrogen gas is caused to flow as the reducing gas, the polarity is switched beforehand to a positive polarity.

At this time, at the same time with the introduction of the mixed gas into the reaction chamber 2, the pressure in the reaction chamber 2 is adjusted to 65 Pa and maintained at this level while the interior of the reaction chamber 2 is being evacuated to a vacuum by the gas exhaust system through the gas exhaust port 2b.

And the introduced cleaning gas etches and removes the adhering films, which have adhered to the inner walls of the reaction chamber 2, the substrate stage 3 and the like, by a halogen-containing radical species which is generated by the contact of the cleaning gas with the catalytic body 4, which has been heated to 1700° C., and by the decomposition thereof, and discharges the removed adhering films through the gas exhaust port 2b.

In this manner, by using the catalytic action of the catalytic body, the catalytic chemical vapor deposition apparatus can be satisfactorily cleaned at practical cleaning rates and besides, the etching of the catalytic body itself can be suppressed.

The cleaning conditions for the cleaning method of a catalytic chemical vapor deposition apparatus of this embodiment are summarized as follows. That is, the pressure in the reaction chamber 2 is 65 Pa, the heating temperature of the catalytic body 4 is 1700° C. or so, the flow rate of NF₃ and H₂ is each 20 sccm, and the diameter of the catalytic body 4 is 0.5 mm.

FIG. 2 shows changes in the voltage generated across the terminals of the heating power supply 6 (the electric potential applied from the heating power supply 6 to the catalytic body 4) in a case where a DC bias voltage is applied from the constant-voltage power supply 8 to the conductor 5b and in a case where this bias voltage is not applied during the cleaning of this embodiment.

In FIG. 2, the character a denotes a case where a bias voltage was not applied from the constant-voltage power supply 8, the character b denotes a case where a bias voltage of +120 V was applied from the constant-voltage power supply 8, and the character c denotes a case where a bias voltage of −180 V was applied from the constant-voltage power supply 8.

In all of the cases, the adhering films which adhere to the inner walls of the reaction chamber 2, the substrate stage 3 and the like were removed well.

As is apparent from the results shown in FIG. 2, in the case where a bias voltage was not applied from the constant-voltage power supply 8 (a of FIG. 2), the voltage generated across the terminals of the heating power supply 6 rose (from about 68 V to about 77.5 V) as the cleaning proceeded.

This is due to the fact that the catalytic body 4 is etched (corrosion-induced degradation) by a halogen element-containing radical species generated by the decomposition of a cleaning gas during cleaning and the diameter of the catalytic body 4 is reduced, whereby the electric resistance of the catalytic body 4 increases.

On the other hand, in the case where a bias voltage of +120 V was applied from the constant-voltage power supply 8 (b of FIG. 2), the rise of the voltage generated across the terminals of the heating power supply 6 is small (from about 81 V to about 84 V) even when the cleaning proceeds and the etching (corrosion-induced degradation) of the catalytic body 4 is suppressed.

Also, in the case where a bias voltage of −180 V was applied from the constant-voltage power supply 8 (c of FIG. 2), the voltage generated across the terminals of the heating power supply 6 rises a little as the cleaning proceeds (from about 78 V to about 82.5 V) and this is due to the etching (corrosion-induced degradation) of the catalytic body 4.

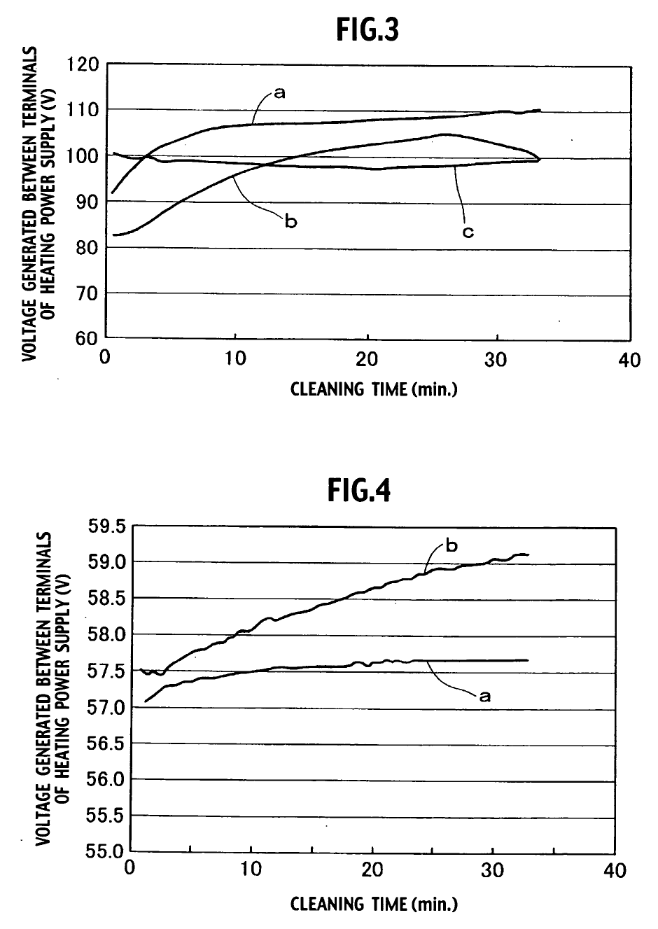

In this embodiment, also when a mixed gas of NF₃ and Ar gas is used as the cleaning gas, FIG. 3 similarly shows changes in the voltage generated between terminals of the heating power supply 6 (the electric potential applied from the heating power supply 6 to the catalytic body 4) in a case where a DC bias voltage is applied from the constant-voltage power supply 8 to the conductor 5b and in a case where this bias voltage is not applied.

In FIG. 3, the character a denotes a case where a bias voltage was not applied from the constant-voltage power supply 8, the character b denotes a case where a bias voltage of +120 V was applied from the constant-voltage power supply 8, and the character c denotes a case where a bias voltage of −180 V was applied from the constant-voltage power supply 8.

In all of the cases, the adhering films which adhere to the inner walls of the reaction chamber 2, the substrate stage 3 and the like were removed well.

The cleaning conditions during this cleaning were as follows. That is, the pressure in the reaction chamber 2 was 65 Pa, the heating temperature of the catalytic body 4 was 1700° C. or so, the flow rate of NF₃ and Ar was each 20 sccm, and the diameter of the catalytic body 4 was 0.5 mm.

As is apparent from the results shown in FIG. 3, in the case where a bias voltage was not applied from the constant-voltage power supply 8 (a of FIG. 3), the voltage generated across the terminals of the heating power supply 6 rose (from about 100 V to about 110 V) as the cleaning proceeded, and the catalytic body 4 was etched (corrosion-induced degradation).

In the case where a bias voltage of +120 V was applied from the constant-voltage power supply 8 (b of FIG. 3), the voltage generated across the terminals of the heating power supply 6 rose (from about 82 V to about 100 V) as the cleaning proceeded, and the catalytic body 4 was etched (corrosion-induced degradation).

On the other hand, in the case where a bias voltage of −180 V was applied from the constant-voltage power supply 8 (c of FIG. 3), the voltage generated across the terminals of the heating power supply 6 scarcely rose even when the cleaning proceeded and the etching (corrosion-induced degradation) of the catalytic body 4 was suppressed.

The results as shown in FIGS. 2 and 3 indicate that the application of a bias voltage from the constant-voltage power supply 8 causes a change in the energy level (related to the Fermi level of the catalytic body 4) of a d-electron in the catalytic body 4 corresponding to the degree of the driving force which reduces or oxidizes an adsorption species on the surface of the catalytic body 4 and of an reception orbit (a d-vacancy) of a donated electron from the adsorption species, and this results in a change in the rate of a surface reaction between a halogen-based radical species which is adsorbed on the surface of the catalytic body 4 and a reducing agent such as H₂, i.e., the rate of the occurrence of etching or the suppression of etching.

Therefore, as shown in FIG. 2, when the cleaning gas is a mixed gas of NF₃ and H₂, the etching (corrosion-induced degradation) of the catalytic body 4 is suppressed in the case where a bias voltage of +120 V is applied from the constant-voltage power supply 8, and as shown in FIG. 3, when the cleaning gas is a mixed gas of NF₃ and Ar gas, the etching (corrosion-induced degradation) of the catalytic body 4 is suppressed in the case where a bias voltage of −180 V is applied from the constant-voltage power supply 8.

As described above, by electrically insulating the heating power supply 6 and conductors 5a, 5b of the catalytic body 4 from the reaction chamber 2 and applying a bias voltage of an appropriate polarity and appropriate value from the constant-voltage power supply 8 to an electric potential across the terminals of the heating power supply 6, i.e., an electric potential to be applied from the heating power supply 6 to the catalytic body 4, it is possible to suppress the carrion-induced degradation of the catalytic body 4 by a cleaning gas and to satisfactorily remove adhering films which adhere to the inner walls of the reaction chamber 2, the substrate stage 3 and the like by the cleaning gas.

Also, it becomes possible to deposit a stable and good film on a substrate even during film formation because the corrosion-induced degradation of a catalytic body 4 by a cleaning gas is suppressed.

Furthermore, because it is unnecessary to heat the catalytic body 4 to not less than 2000° C. during cleaning as in conventional examples, neither the degradation due to the evaporation of the catalytic body 4 itself or the pollution of the interior of the reaction chamber 2 with the component elements of the catalytic body 4 due to the evaporation occurs. In addition, it becomes possible to reduce cost because inexpensive members having a low melting point can be used.

### Embodiment 2

Next, Embodiment 2 will be described.

In this embodiment, the self-cleaning catalytic chemical vapor deposition apparatus 1 shown in FIG. 1 is used and a zero bias voltage is applied without applying a bias voltage from the constant-voltage power supply 8 to the voltage generated across the terminals of the heating power supply 6.

The cleaning conditions in this embodiment are as follows. The pressure in the reaction chamber is 10 Pa, the wire diameter of the catalytic body is 0.7 mm, and the heating temperature of the catalytic body is 1700° C. As the cleaning gas, a mixed gas of NF₃ and H₂ was introduced each at a flow rate of 20 sccm.

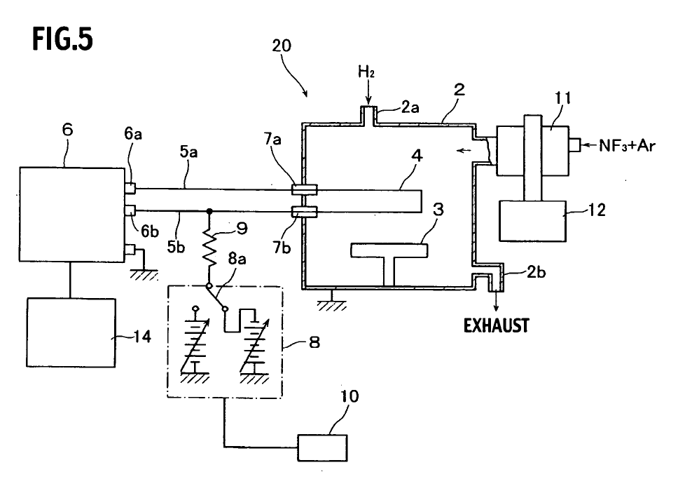

FIG. 4 is a diagram which shows the relationship between the voltage generated between terminals of the heating power supply indicative of the occurrence of etching of the catalytic body itself and the cleaning time of Embodiment 2. The character a denotes a case where a mixed gas of NF₃ and H₂ is used as the cleaning gas related to Embodiment 2 and the character b denotes a case where a mixed gas of NF₃ and Ar is used as the cleaning gas as a comparative example.

As shown in FIG. 4, because in Embodiment 2, the gradient of the voltage generated across the terminals of the heating power supply is flat, the etching of the catalytic body itself scarcely occurs and the adhering films within the reaction chamber can be removed well.

For a comparison, the figure also shows changes in the voltage across the terminals of the heating power supply 6, i.e., an electric potential to be applied from the heating power supply 6 to the catalytic body 4 during cleaning (see the character b in FIG. 4) in the case where “a mixed gas of NF₃ and Ar” is used.

The cleaning conditions of this comparative example are the same as those of Embodiment 2, and the flow rate of NF₃ and Ar is each 20 sccm.

As is apparent from the results shown in FIG. 4, the rise of the voltage generated across the terminals of the heating power supply 6 in the course of cleaning is by far smaller in the case where a mixed gas of NF₃ and H₂ is used as the cleaning gas than in the case where a mixed gas of NF₃ and Ar is used, and the etching (corrosion-induced degradation) of the catalytic body 4 is suppressed.

From the results shown in FIG. 4, it might be thought that when a mixed gas of NF₃ and Ar is used as the cleaning gas, the etching (corrosion-induced degradation) of the catalytic body 4 proceeds because of the existence of a reaction path in which part of a fluorine-containing radical species generated by the contact of NF₃ with the heated catalytic body (tungsten wire) 4 and the decomposition thereof the catalytic body 4 itself as a reducing agent under the formation of tungsten fluoride (WFₓ: usually, x≦6).

On the other hand, when a mixed gas of NF₃ and H₂ is used as the cleaning gas, a hydrogen radical generated by the contact of H₂ with the heated catalytic body (tungsten wire) 4 and the decomposition thereof is also present, and this hydrogen radical acts on the fluorine-containing radical species as a reducing agent which is competitive with the catalytic body 4. It might be thought, therefore, that a reaction path in which hydrogen fluoride (HF) is generated is also formed in an alternative way, with the result that the etching (corrosion-induced degradation) of the catalytic body 4 is suppressed.

It might be thought that also the lower pressure in the reaction chamber 2 than in Embodiment 1 contributes to the suppression of the etching (corrosion-induced degradation) of the catalytic body 4.

Also by using a mixed gas of NF₃ and H₂ is used as the cleaning gas in this manner, it is possible to remove the adhering films adhering to the interior of the reaction chamber and also to suppress the etching (corrosion-induced degradation) of the catalytic body 4.

### Embodiment 3

Next, Embodiment 3 will be described.

FIG. 5 is a schematic block diagram showing the self-cleaning catalytic chemical vapor deposition apparatus related to Embodiment 3.

Incidentally, like reference numerals refer to members having the same function as the self-cleaning catalytic chemical vapor deposition apparatus shown in FIG. 1 and overlapping descriptions of these members are omitted.

This self-cleaning catalytic chemical vapor deposition apparatus 20 is provided, on the outer side of the reaction chamber 2, with a vessel for cleaning gas decomposition 11 as a radical generator which decomposes a cleaning gas and generates a radical species.

The vessel for cleaning gas decomposition 11 is provided with a plasma generator 12 of RF plasma, microwave plasma and the like, and can generate halogen-containing radical species by the plasma decomposition of an introduced clean gas, for example, a mixed gas of NF₃ and Ar by electromagnetic energy.

As the decomposition means of an introduced cleaning gas, means other than plasma, for example, optical energy by the irradiation with ultraviolet rays may be used.

Other constituent features are the same as in the self-cleaning catalytic chemical vapor deposition apparatus 1 according to Embodiment 1 shown in FIG. 1.

Hereinafter, an in situ cleaning method in this embodiment will be described.

First, while the interior of a reaction chamber 2 is being purged with an inert gas, the interior of the reaction chamber 2 is evacuated to a vacuum by a gas exhaust system (not shown) through a gas exhaust port 2b and the pressure is adjusted to a prescribed pressure, for example, 65 Pa.

And resistance heating is performed by applying a DC voltage from a heating power supply 6 to a catalytic body 4 via conductors 5a, 5b and the catalytic body 4 is heated to a prescribed temperature, for example, 1700° C. or so.

At this time, because Ar gas is used as the inert gas, a bias voltage is applied beforehand, with the polarity set at a negative polarity.

Next, the cleaning gas, a mixed gas of NF₃ and Ar in this embodiment is introduced into the vessel for cleaning gas decomposition 11 while the pressure being adjusted and maintained at 65 Pa.

This introduced cleaning gas, i.e., the mixed gas of NF₃ and Ar is subjected to plasma decomposition by the plasma generator 12 under the generation of a halogen-containing radical species, this halogen-containing radical species is supplied into the reaction chamber 2, whereby adhering films adhering to the inner walls of the reaction chamber 2, the substrate stage 3 and the like and removed by etching and discharged through the gas exhaust port 2b.

On this occasion, in the same manner as in Embodiment 1, a bias voltage having an appropriate polarity and an appropriate value is applied by the control of a controller 10 from a constant-voltage power supply 8 to an electric potential across the terminals of the heating power supply 6 (an electric potential applied from the heating power supply 6 to the catalytic body 4).

As a result of this, as described in Embodiment 1, it is possible to suppress the corrosion-induced degradation of the catalytic body 4 by a halogen-containing radical species.

During the cleaning of this embodiment, by introducing H₂ as a reducing gas into the reaction chamber 2 through a gas supply port 2a, it is possible to more satisfactorily suppress the corrosion-induced degradation of the catalytic body 4 by a halogen-containing species as described in Embodiment 2.

Although in this embodiment H₂ is supplied into the reaction chamber 2 from the gas supply port 2a, it is also possible to introduce H₂ along with the cleaning gas into the vessel for cleaning gas decomposition 11 and to supply H₂ into the reaction chamber 2 through the vessel for cleaning gas decomposition 11.

As described above, by decomposing the cleaning gas in the vessel for cleaning gas decomposition 11 provided outside the reaction chamber 2 and supplying a generated halogen—containing radical species into the reaction chamber 2 where adhering films are removed, whereby it is possible to remove the adhering films more efficiently than in the case of Embodiment 1 where the cleaning gas is decomposed by the heated catalytic body 4 within the reaction chamber 2 and hence it is possible to shorten the cleaning time.

Although in the cleaning methods of the above-described embodiments NF₃ is used as the cleaning gas, it is also possible to use other gases, for example, halogen-containing gases, such as HF, C₂F₆, C₃F₈, SF₆, CF₄, CClF₃, C₂ClF₅ and CCl₄.

### INDUSTRIAL APPLICABILITY

In a self-cleaning catalytic chemical vapor deposition apparatus and a cleaning method of the apparatus of the present invention, cleaning to remove adhering materials is performed by using the catalytic action of a resistance-heated catalytic body. However, because it is possible to suppress the etching of the catalytic body itself and to remove only the adhering materials, the present invention is useful in the cleaning of a catalytic chemical vapor deposition apparatus which forms a thin film by catalytic action.

1. A self-cleaning catalytic chemical vapor deposition apparatus which forms a thin film by using the catalytic action of a catalytic body which is resistance heated within a reaction chamber capable of being evacuated to a vacuum, characterized in that the apparatus comprises a power supply to apply a bias voltage to the catalytic body and a changeover switch which changes the polarity of the bias voltage to be applied, and which removes an adhering film which has adhered to the interior of the reaction chamber without etching the catalytic body itself on the basis of a radical species generated when an introduced cleaning gas comes into contact with the resistance heated catalytic body and is decomposed, the bias voltage applied to the catalytic body, and a polarity of the bias voltage.

2. The self-cleaning catalytic chemical vapor deposition apparatus according to claim 1, characterized in that in addition to the aforementioned constitution, a radical species generator which decomposes the cleaning gas into a radical species and introduces the radical species into the reaction chamber is provided.

3. The self-cleaning catalytic chemical vapor deposition apparatus according to claim 1, characterized in that the cleaning gas is a mixed gas of a halogen-containing gas and either an inert gas or a reducing gas.

4. The self-cleaning catalytic chemical vapor deposition apparatus according to claim 1, characterized in that the cleaning gas contains either an inert gas or a reducing gas and that a polarity of the bias voltage based on the kind of the inert gas and the reducing gas is obtained.

5. The self-cleaning catalytic chemical vapor deposition apparatus according to claim 1, characterized in that the cleaning gas is a mixed gas of a halogen—containing gas and a reducing gas when the bias voltage of the prescribed polarity is zero.

6. The self-cleaning catalytic chemical vapor deposition apparatus according to claim 3, characterized in that the halogen—containing gas is any of gases selected from the group consisting of NF₃, HF, C₂F₆, C₃F₈, SF₆, CF₄, CClF₃, C₂ClF₅ and CCl₄ or combinations of the gases, that the reducing gas is H₂, and that the inert gas is a noble gas.

7. The self-cleaning catalytic chemical vapor deposition apparatus according to claim 1, characterized in that the cleaning gas is a mixed gas of a halogen—containing gas and H₂ and that the bias voltage of a positive polarity is applied.

8. The self-cleaning catalytic chemical vapor deposition apparatus according to claim 1, characterized in that the cleaning gas is a mixed gas of a halogen—containing gas and Ar and that the bias voltage of a negative polarity is applied.

9. The self-cleaning catalytic chemical vapor deposition apparatus according to claim 1, characterized in that there is provided a monitoring device which detects the occurrence of etching of the catalytic body itself on the basis of electric resistance of the catalytic body.

10. A cleaning method of a catalytic chemical vapor deposition apparatus which forms a thin film by using the catalytic of a catalytic body which is resistance heated within a evacuated to a vacuum, the of applying a bias voltage action reaction chamber capable of being cleaning method comprising a step of a prescribed polarity to a catalytic body which is resistance heated, a step of introducing a cleaning gas, a step in which the cleaning gas comes into contact with the catalytic body which has been resistance heated and is decomposed to generate a radical species, and a step of removing an adhering film which has adhered to the interior of a reaction chamber without etching the catalytic body itself.

11. The cleaning method of a catalytic chemical vapor deposition apparatus according to claim 10, characterized in that the step of introducing a cleaning gas is a step of decomposing the cleaning gas into a radical species and introducing the radical species into the reaction chamber.

12. The cleaning method of a catalytic chemical vapor deposition apparatus according to claim 10, characterized in that the cleaning gas is a mixed gas of a halogen-containing gas and either an inert gas or a reducing gas.

13. The cleaning method of a catalytic chemical vapor deposition apparatus according to claim 10, characterized in that the cleaning gas contains either an inert gas or a reducing gas and that a bias voltage of a polarity determined on the basis of the kind of the inert gas and the reducing gas is applied.

14. The cleaning method of a catalytic chemical vapor deposition apparatus according to claim 10, characterized in that the cleaning gas is a mixed gas of a halogen—containing gas and a reducing gas when the bias voltage of the prescribed polarity is zero.

15. The cleaning method of a catalytic chemical vapor deposition apparatus according to claim 12, characterized in that the halogen—containing gas is any of gases selected from the group consisting of NF₃, HF, C₂F₆, C₃F₈, SF₆, CF₄, CClF₃, C₂ClF₅ and CCl₄ or combinations of the gases, that the reducing gas is H₂, and that the inert gas is a noble gas.

16. The cleaning method of a self-cleaning catalytic chemical vapor deposition apparatus according to claim 10, characterized in that the cleaning gas is a mixed gas of a halogen—containing gas and H₂ and that the bias voltage of a positive polarity is applied.

17. The cleaning method of a catalytic chemical vapor deposition apparatus according to claim 10, characterized in that the cleaning gas is a mixed gas of a halogen—containing gas and Ar and that the bias voltage of a negative polarity is applied.

18. The cleaning method of a catalytic chemical vapor deposition apparatus according to claim 10, characterized in that in addition to the aforementioned constitution, the occurrence of etching of the catalytic body itself is monitored in situ on the basis of electric resistance during cleaning.
